(19) United States
(12) Patent Application Publication
(10) Pub. No.: US 2024/0019781 A1
(43) Pub. Date: Jan. 18, 2024

(54) DISPERSION RESIN, PREPARATION METHOD THEREFOR AND PHOTORESIST COMPOSITION

(71) Applicant: ShenZhen Brthrborder Semiconductor Materials Co., Ltd., Shenzhen (CN)

(72) Inventors: Meidi ZHONG, Shenzhen (CN); Yulong CHEN, Shenzhen (CN); Xiangjun YUN, Shenzhen (CN); Wei LI, Shenzhen (CN); Guangfu REN, Shenzhen (CN); Xia YANG, Shenzhen (CN)

(73) Assignee: ShenZhen Brthrborder Semiconductor Materials Co., Ltd., Shenzhen (CN)

(21) Appl. No.: 18/473,313

(22) Filed: Sep. 25, 2023

Related U.S. Application Data
(63) Continuation-in-part of application No. PCT/CN2022/101147, filed on Jun. 24, 2022.

(51) Int. Cl. G03F 7/038; G03F 7/029; G03F 7/004; C09D 17/00

(52) U.S. Cl. CPC G03F 7/0382; G03F 7/029; G03F 7/0048; C09D 17/002

(57) ABSTRACT

The present invention provides a dispersion resin and a preparation method therefor, and a low-temperature cured photoresist composition. The dispersion resin is represented by a formula (2): (Z-A)ₙ—Rₘ (2), n=1-5, m=1-5, and n+m<=6; Z represents H, or an acrylic copolymer containing an amino group, an epoxy group, an alkyl group having 1-14 carbon atoms, a cycloalkyl group having 3-14 carbon atoms or an aryl substituent; R represents C, N, CH groups,

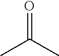

or at least one of linear alkyl, aliphatic cycloalkyl, aryl and heteroaryl containing 6-14 carbon atoms; A is represented by formula (3):

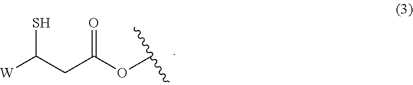

In formula (3), W is linked to Z, the carboxyl group is linked to R, and W represents at least one of an H atom, a substituted or unsubstituted alkyl group having 1-14 carbon atoms, an alkylene oxide group having 2-6 carbon atoms, a substituted or unsubstituted aryl group and a substituted or unsubstituted heteroaryl group having 3-14 carbon atoms.

### TECHNICAL FIELD

The present invention relates to the technical field of a dispersion resin and photoresist, in particular to a dispersion resin, a preparation method therefor, and a photoresist composition.

### BACKGROUND OF THE INVENTION

There are various methods for processing devices with color photoresists, such as dyeing method, pigment dispersion method, printing method, electrodeposition method, inkjet method, etc. Among them, the pigment dispersion involves dispersing organic/inorganic pigments in a resin solution, and then coating a colored photoresist on a glass/PET/CPI/metal substrate; After exposure, development and other photolithography process, the color layer of a color filter can be made, which has the advantages of fine process, light resistance, contrast, high color saturation and stable performance.

The color filter is a key component of liquid crystal display that can be colored, and its manufacturing technique and quality using color photoresist have a crucial impact on the display performance of liquid crystal displays. At present, liquid crystal devices with color filters are increasingly used in notebook computers, smartphones, car displays, and large liquid crystal televisions. These liquid crystal devices require high color and contrast requirements.

Polarizing plate, which is a device that must be relied on for imaging of liquid crystal displays and OLED displays. Both front and rear polarizers are clung to the upper and lower surfaces of the display screen. The basic structure of the traditional polarizes includes: PVA (polyvinyl alcohol) in the middle, two layers of TAC (cellulose triacetate), PSA film (pressure sensitive adhesive), release film, and protective film.

As the decrease of the temperature of the flexible display manufacturing process or the shortening of the high temperature operation time, that is, the application of low-temperature coating and its related technology is increasing, and the requirements for low temperature cured photoresists are also increasing. The core of these products is a low temperature cured negative photoresists, and on the basis of adding pigment liquid can modulate the color of the low temperature curing products.

The technology of polarized light emission for flexible OLED displays using traditional polarizers can significantly reduce the luminous efficiency of flexible OLED devices. Therefore, display device manufacturers such as Samsung Display in South Korea proposed to adopta method of using color filters to create a layer of color pixels on the red, green, and blue primary color pixels of OLED to solve the problem of polarized light. Such color photoresists are required to be low temperature cured photolithographic materials.

The patent JP2005-380016 discloses that the method of adding black matrix to a red, green, and blue color filters is the most representative traditional filter structure, with the pixel width in the range of 20 um. And patent CN201210070934 to solve some flatting and coupling problems, but because the dispersion resin and grinding resin used in the pigment paste cannot completely match and unify the polarity of the developing resin in the photoresist during the preparation of the photoresist, it is unable to improve pixel accuracy, especially the resolution of the pixel edges.

In order to adapt to the continuous upgrading of LCD color performance requirements, in addition to the need to finely pigment dispersion, the polymer preparation in the pigment photoresist is also optimized to produce below 10 μm graphics and prepare red, yellow, blue, and green, or red, blue, and green color filters.

In addition, some new devices also require some special below 10 μm pattern size, and are marked with colors such as red, green, blue, yellow, magenta, cyan, black, or white. These below 10 μm fine patterns with colors can be made on different types of PET or metal sheets.

### SUMMARY OF THE INVENTION

In order to overcome the shortcomings of the prior art, the invention aims to provide a dispersion resin suitable for low temperature curing (85-100° C.) and a preparation method thereof and a photoresist composition. A method is also provided for the preparation of dispersion resin intermediate, nano pigment pigment paste composition and the preparation of low temperature color photoresist on the substrate by the photolithography after drying process, the dispersion resin used in the photoresist composition can make the nano pigment in the low temperature curing photoresist system in the state of dispersion of fine particles, so that the pigment particles can not agglomerate flocculation.

To solve the above problems, the technical scheme of the invention is as follows:

A dispersion resin, which is represented by formula (2):

(Z-A)ₙ—Rₘ (2),
in formula (2), n=1-5, m=1-5, and n+m≤6;
Z represents H, or an acrylic copolymer containing an amino group, an epoxy group, an alkyl group having 1-14 carbon atoms, a cycloalkyl group having 3-14 carbon atoms or an aryl substituent;
R represents C, N, CH groups,

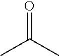

or at least one of linear alkyl containing 2-14 carbon atoms, aliphatic cycloalkyl containing 2-14 carbon atoms, aryl group and heteroaryl group containing 3-14 carbon atoms;
A is represented by formula (3):

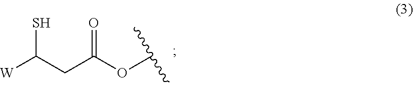

in formula (3), W is linked to Z, the carboxyl group is inked to R, and W represents at least one of an H atom, a substituted or unsubstituted alkyl group having 1-14 carbon atoms, an alkylene oxide group having 2-6 carbon atoms, a substituted or unsubstituted aryl group and a substituted or unsubstituted heteroaryl group having 3-14 carbon atoms.

In some alternative embodiments, n=1-3, m=1-3, and n+m≤4, and/or
Z represents a copolymer formed by more than one compound selected from the group consisting of methacrylic acid, acrylic acid, benzyl acrylate, styrene, methyl methacrylate, butyl methacrylate, isobornyl methacrylate, glycidyl methacrylate, dicyclopentanyl methacrylate, hydroxyethyl methylacrylate, hydroxybutyl acrylate, N-phenyl maleimide, maleic anhydride, 2-acrylic acid-2 hydroxy-3-phenoxypropyl acrylate or pentaerythritol acrylate, and/or
W represents at least one of H, methyl, ethyl, and hydroxy substituted alkyl, epoxy alkyl, phenyl, benzyl, and phenolic groups.
Z represents an acrylic copolymer with an Mw of 5000-10000, a Pd value of less than 2.5, and a viscosity of less than 5000 cps.

A represents at least one of the compounds represented by the following:

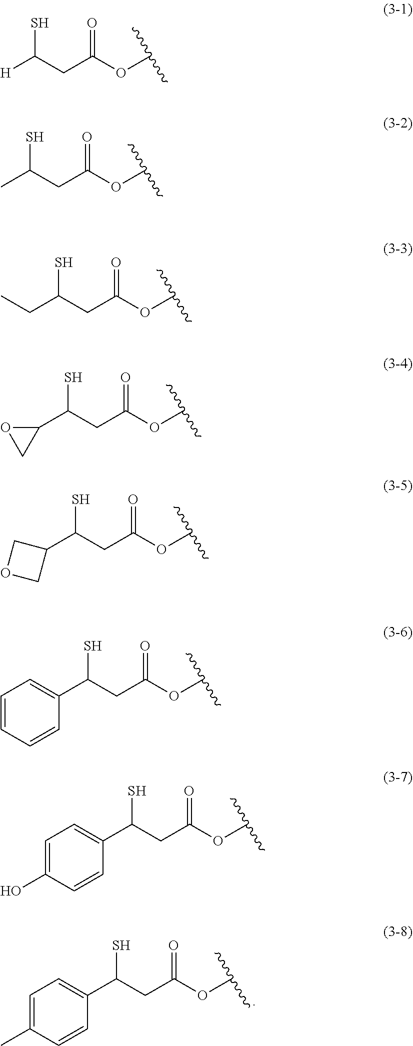

An intermediate used for preparing the dispersion resin according to any one of the above, the intermediate is represented by formula (4):

(X-A)ₙ—Rₘ (4),

In formula (4), X represents halogen;
n=1-5, m=1-5, and n+m<6;
R represents C, N, CH groups,

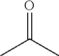

or at least one of linear alkyl containing 2-14 carbon atoms, aliphatic cycloalkyl containing 2-14 carbon atoms, aryl group and heteroaryl group containing 3-14 carbon atoms;
A is represented by formula (3):

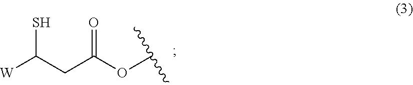

in formula (3), W is linked to X, the carboxyl group is linked to R, and W represents at least one of an H atom, a saturated or unsaturated alkyl group having 1-14 carbon atoms, an epoxy group having 2-6 carbon atoms, a substituted or unsubstituted aryl group and a substituted or unsubstituted heteroaryl group having 3-14 carbon atoms.

In some alternative embodiments, X is Cl, Br or I,
n=1-3, m=1-3, and n+m<4, and/or
W represents at least one of H, methyl, ethyl, and hydroxy substituted alkyl, epoxy alkyl, phenyl, benzyl, and phenolic groups.

In some alternative embodiments, the intermediate is one of the compounds represented by the following:

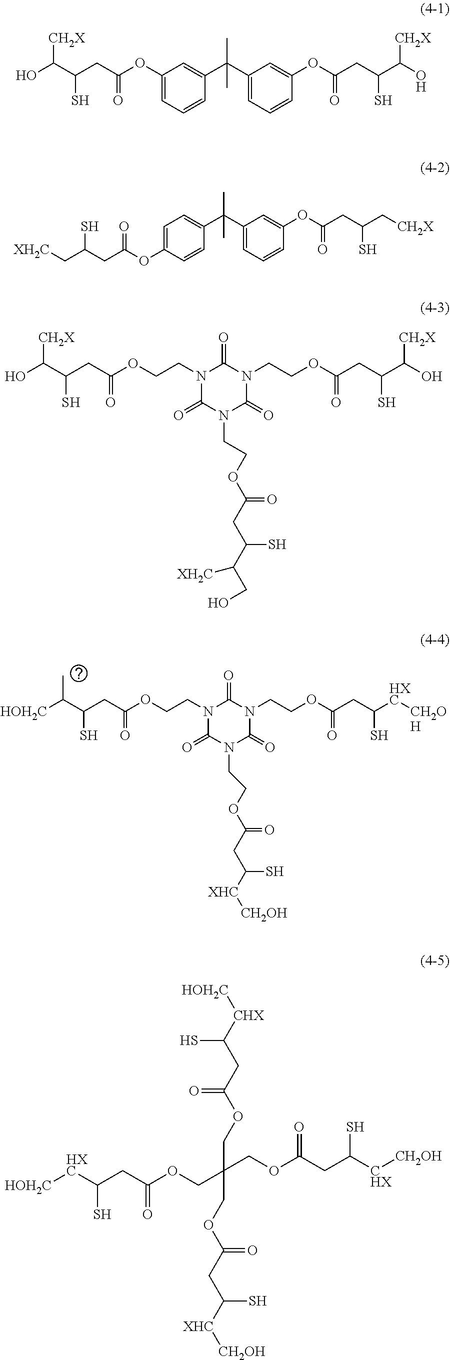

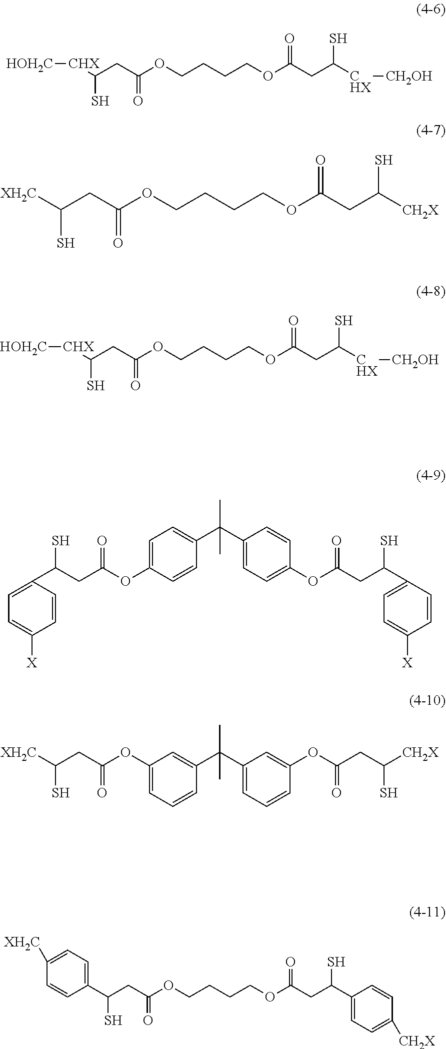

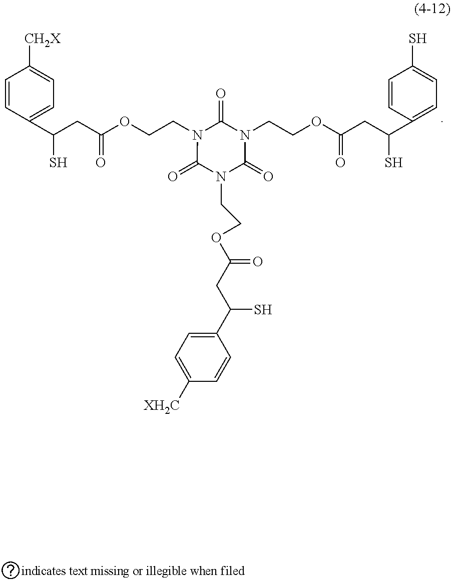

As described above, in formulae (4-1) to (4-12), X represents halogen, preferably Cl, Br, or I, more preferably Br.

A method for preparing the dispersion resin according to any one of the above, the method comprises the following steps:
under the action of a radical initiator, acrylic compounds containing amino groups, epoxy groups, alkyl groups having 1-14 carbon atoms, and cycloalkyl group or aryl substituents having 3-14 carbon atoms are added to a first solvent containing a chain transfer agent, and an acrylic copolymer Z is generated through radical solution polymerization under an inert atmosphere.

The obtained acrylic copolymer Z is reacted with the intermediate according to any one of the above in the presence of a catalyst in a second solvent to generate a dispersion resin.

According to the preparation method of the dispersion resin of the present invention, the dispersion resin of the present invention can be effectively prepared.

In the preparation method of the dispersion resin of the present invention, the obtained acrylic copolymer Z and the intermediate are heated, dissolved, and refluxed for 2-5 Hr in a second solvent in the presence of a catalyst, and then stirred for 5-12 Hr at 70-120° C. to generate the dispersion resin. The mass ratio of the acrylic copolymer Z to the intermediate is 1:1 to 1.5:1.

In the preparation method of the dispersion resin of the present invention, the obtained acrylic copolymer Z and the intermediate are heated, dissolved, and refluxed for 3.5 Hr in a second solvent in the presence of a catalyst, and then stirred for 8 Hr at 90° C. to generate the dispersion resin. The mass ratio of the acrylic copolymer Z to the intermediate is 1.2:1.

In the preparation method of the dispersion resin of the present invention, the acrylic compound is more than one compound selected from the group consisting of methacrylic acid, acrylic acid, benzyl acrylate, styrene, methyl methacrylate, butyl methacrylate, isobornyl methacrylate, glycidyl methacrylate, dicyclopentanyl methacrylate, hydroxyethyl methylacrylate, hydroxybutyl acrylate, N-phenyl maleimide, maleic anhydride, 2-acrylic acid-2 hydroxy-3-phenoxypropyl acrylate or pentaerythritol acrylate. The first solvent and the second solvent are each at least one selected from the group consisting of toluene, ethyl acetate, DMF, NMP, DMSO, and acetonitrile. The catalyst is at least one selected from the group consisting of tetramethyl guanidine, TMG, KI, NaI, triethylamine, and metformin.

After the solvent has been rotatorially evaporated, n-butanol (1.5 times the volume of the original reaction solvent) can be read, for example, at 55° C., for 1 Hr, added to petroleum ether (for example, 3 times the volume), and the precipitate is drained and dried to obtain dispersion resin.

A nano pigment paste composition, the nano pigment paste composition comprises the following components by weight parts:
5-30 parts of nano pigment;
0.5-5 parts of hyperdispersant;
0.5-5 parts of the dispersion resin according to any one of the above; and
15-75 parts of organic solvent.

The parts of nano pigment by weight are, for example, 10 parts, 15 parts, 20 parts or 25 parts; the parts of hyperdispersant by weight are, for example, 1 part, 2 parts, 3 parts or 4 parts; the parts of dispersion resin by weight are, for example, 1 part, 2 parts, 3 parts or 4 parts; the parts of organic solvent by weight are, for example, 20 parts, 30 parts, 40 parts, 50 parts, 60 parts, 65 parts or 70 parts.

Generally, a method for making pigment paste based on chromaticity requirements includes mixing and grinding two or more pigment crystals when dispersing the paste, for example, red color can be direct mixing and grinding of PR177 and PR254, or direct mixing and grinding of PR254 and PY138; green color can be direct mixing and grinding of PG36 and PY 150, or direct mixing and grinding of PG58 and PY 150; blue color can be direct mixing and grinding of PB15:4 and PV19, or direct mixing and grinding of PB15:6 and PV23; black color can be direct mixing and grinding of C black and titanium black; white color can be direct grinding of titanium oxide.

In some alternative embodiments, the nano pigment paste composition has an average particle size D50 of 10-200 nm, a bulk density of 0.5-4.8 g/cm³, and a specific surface area of 100-400 m²/g.

In some alternative embodiments, the nano pigment paste composition has an average particle size D₅₀ of 20-200 nm, a bulk density of 0.7-1.8 g/cm³, and a specific surface area of 100-200 m²/g.

In some alternative embodiments, the nano pigment is at least one of red, yellow, blue, green, black, and white organic and/or inorganic nano pigments. Nano pigment can be organic pigment or inorganic pigment: The main organic pigments available are red for PR177 and PR254; green for PG36 and PG58; blue for PB 15:4 and PB 15:6; yellow for PY138 and PY 150; purple for PV 19 and PV23. However, the inorganic metals, their oxides, and carbon black particles: white for TiO₂ and SiO₂; black for C black 7, C black 11, titanium black, iron oxide.

In the present invention, in addition to selecting pigments, the paste composition is also subjected to wet dispersion. The hyperdispersant is at least one of a copolymer of methacrylic acid and styrene, a polyester copolymer, a polyurethane copolymer, and an epoxy resin copolymer. Examples of products available in the market mainly include the following trade names: EFKA-4060, EFKA-4080, EFKA-4043, EFKA-4047, Disperbyk-2000, Disperbyk-2001, Disperbyk-161-167, Disperbyk-2050, Disperbyk-2100, Disperbyk-2020, Disperbyk-333, Solsperse28000, Solsperse24000, Solsperse5000, Solsperse22000, Solsperse32500, Solsperse38500.

The organic solvent is at least one of propylene glycol monomethyl ether, propylene glycol methyl ether acetate, ethyl 3-ethoxypropionate, and butyl acetate.

A photoresist composition, the photoresist composition comprises the following components by weight parts:

nano pigment paste composition according
to any one of the above

| | |
|---|---|
| alkali-soluble resin | 1-50 parts; |
| Oligomeric resin | 1-20 parts; |
| Photoinitiator | 0.2-2 parts; |
| active aid | 0.02-2 parts; |
| light-cured resin | 1-15 parts; |
| polar organic solvent | 20-200 parts. |

The parts of nano pigment paste composition by weight are, for example, 5 parts, 10 parts, 20 parts, 30 parts, 40 parts or 45 parts; the parts of alkali-soluble resin by weight are, for example, 3 parts, 5 parts, 7 parts, 10 parts, 12 parts, 14 parts, 16 parts or 18 parts; the parts of resin oligomer by weight are, for example, 3 parts, 5 parts, 7 parts, 10 parts, 12 parts, 14 parts, 16 parts or 18 parts; the parts of photoinitiator by weight are, for example, 0.4 parts, 0.7 parts, 1 part, 1.2 parts, 1.4 parts, 1.6 parts or 1.8 parts; the parts of active aid by weight are, for example, 0.05 parts, 0.1 parts, 0.15 parts, 0.2 parts, 0.4 parts, 0.6 parts, 0.8 parts, 1 part, 1.2 parts, 1.5 parts or 1.8 parts; the parts of light-cured resin by weight are, for example, 3 parts, 5 parts, 6 parts, 7 parts, 8 parts, 9 parts, 10 parts or 12 parts; the parts of polar organic solvent by weight are, for example, 30 parts, 40 parts, 50 parts, 80 parts, 100 parts, 120 parts, 140 parts, 160 parts or 180 parts.

In the above solution, the “alkali-soluble resin” refers to a polymer resin containing alkyl methacrylate groups. The average acid value of the alkali-soluble resin is 60 KOH/g-200 KOH/g, preferably 90 KOH/g-150 KOH/g. In some alternative embodiments, the alkali-soluble resin is at least one selected from the group consisting of a methacrylic acid—methyl methacrylate copolymer, a methacrylic acid—cyclohexyl methacrylate copolymer, a methacrylic acid—epoxypropyl methacrylate copolymer, a methacrylic acid—2-hydroxyethyl methacrylate copolymer, a methacrylic acid—cyclohexyl methacrylate copolymer, and a styrene—2-hydroxyethyl methacrylate copolymer, and/or

The light-cured resin is a light-cured resin with a vinyl double bond, and the light-cured resin is at least one selected from the group consisting of acrylated epoxidized soybean oil, modified epoxy acrylate, polyester acrylate, active amine, HDDA, TMPTA, DPGDA, PETA, IOBA, EB114, EB145, EB160, ODA, TCDA and OTA480.

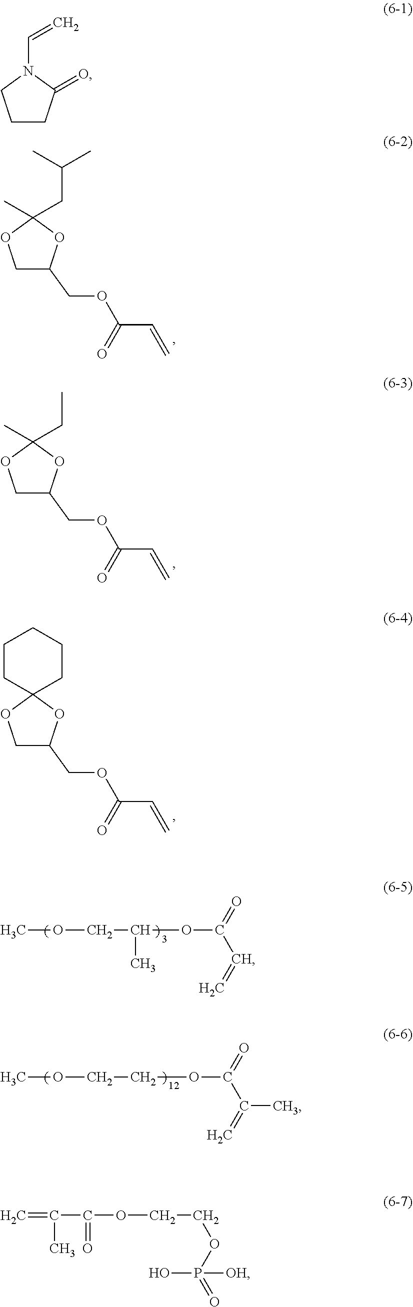

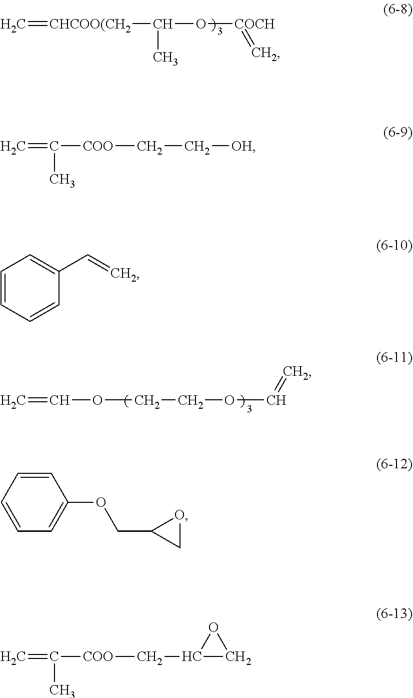

The photoinitiator is at least one selected from the group consisting of diphenyl (2,4,6-trimethylbenzoyl) phosphine oxide, 1-hydroxycyclohexylphenyl ketone, 2-benzyl-2-(dimethylamino)-4′-morpholinobutyrylbenzene, 2-methyl-1-[4-methylthiophenyl]-2-morpholinopropan-2-one, 2-hydroxy-2-methyl-1-phenyl-1-acetone, 2-isopropylthioxanthone, 4-dimethylaminobenzoate, 4-dimethylaminobenzoate 2-ethylhexyl acrylate, methyl o-benzoylbenzoate and 4-methylbenzophenone.

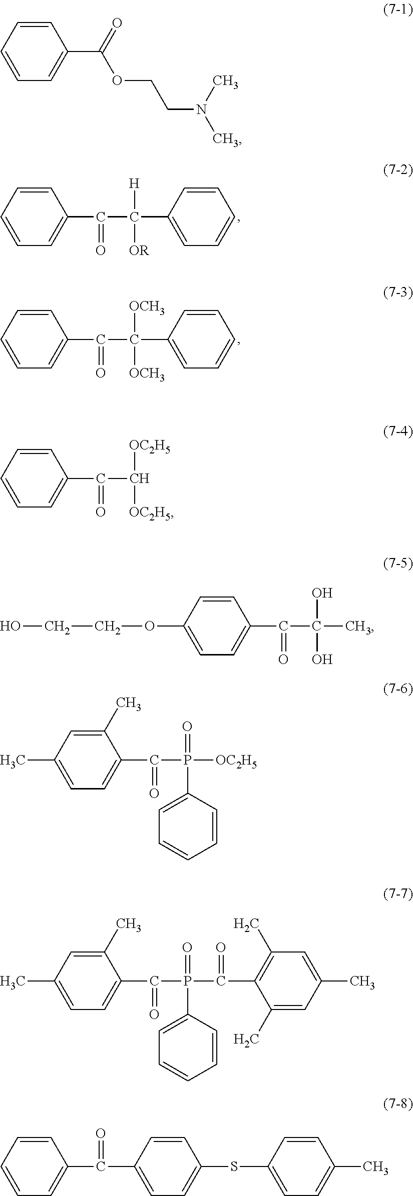

The active aid is at least one of a flatting agent and a coupling agent, wherein the flatting agent is at least one selected from the group consisting of a polyether modified polydimethylsiloxane solution, a polyester modified polydimethylsiloxane solution, a polyether modified polysiloxane solution, a polyester modified polymethylalkylsiloxane solution, a polyether modified polydimethylsiloxane solution, a polyether modified polydimethylsiloxane solution, a polyacrylate solution and a fluorocarbon copolymer solution, and the coupling agent is at least one selected from the group consisting of N′-β′-aminoethyl-N-β-aminoethyl-γ-aminopropylmethyldimethoxysilane, N′-β′-aminoethyl-N-β-aminoethyl-γ-aminopropylmethyldimethoxysilane, N-β′-aminoethyl-N-β-aminoethyl-γ-aminopropylmethyldiethoxysilane, N′-β′-aminoethyl-N-β-aminoethyl-γ-aminopropyltrimethoxysilane, N′-β′-aminoethyl-N-β-aminoethyl-γ-aminopropyltriethoxysilane and N-β′-aminoethyl-N-β-aminoethyl-α-aminomethyl triethoxysilane, γ-cyclohexylaminopropyltriethoxysilane and methyl, γ-cyclohexylaminopropyldimethoxysilane and γ-chloropropyltriethoxysilane (γ2).

The polar organic solvent is preferably a low-polarity organic solvent or a medium-polarity organic solvent, and the organic solvent is at least one selected from the group consisting of methyl ethyl ketone, ethyl cellosolve, glycol dimethyl ether, ethylene glycol diethyl ether, propylene glycol dimethyl ether, diethylene glycol dimethyl ether, 2-ethoxypropanol, 2-methoxypropanol, 3-methoxybutanol, cyclohexanone, cyclopentanone, propylene glycol methyl ether acetate, propylene glycol diethyl ether acetate, and butyl acetate.

The oligomer resin is represented by formulae (1-1), (1-2) or (1-3):

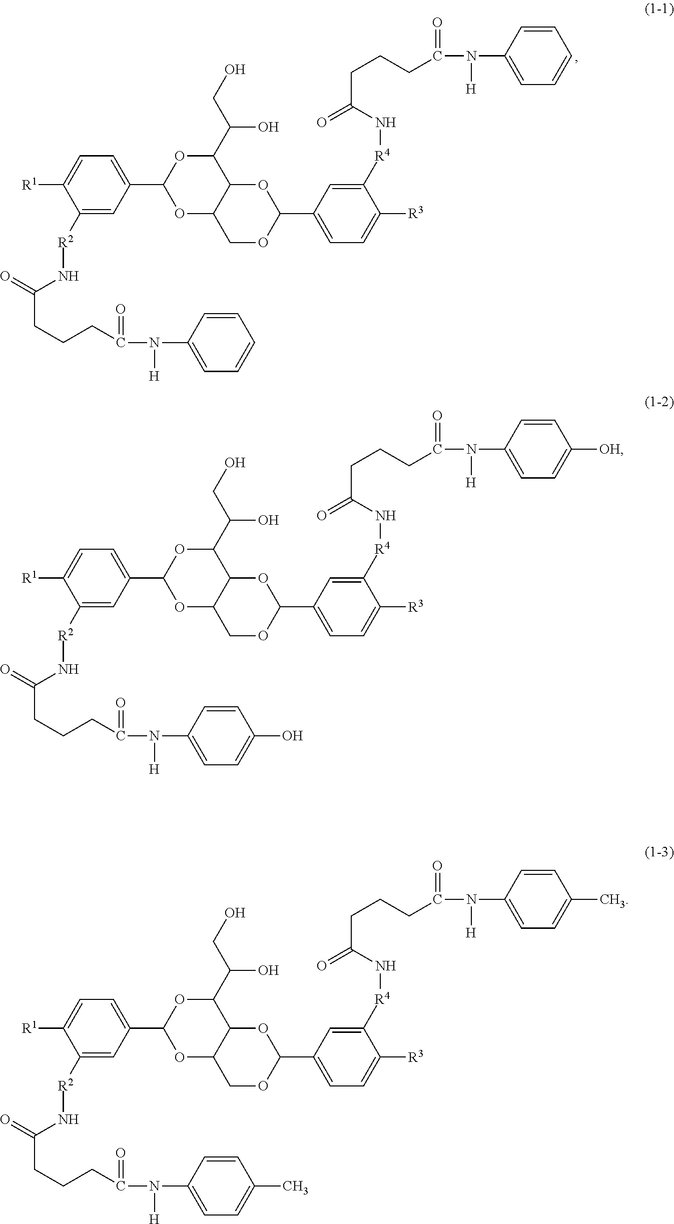

In formulae (1-1), (1-2) and (1-3), R¹ and R³ each represent linear hydrocarbyl group or grafted copolymer groups having 2-8 carbon atoms, and R² and R⁴ each represent C, benzene ring

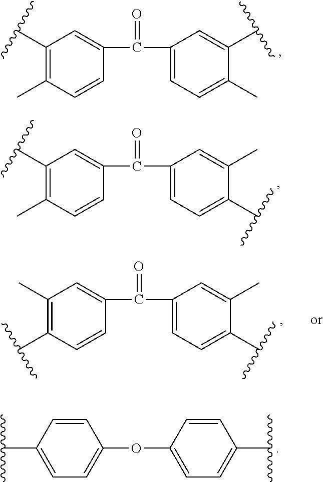

In some alternative embodiments, the oligomer resin has an Ms value of 3000-8000; a weight-average molecular weight (Mw value) of 6000-20000; a Pd value of around 1.8.

As an example, the photoresist composition of the present invention can be prepared by the following methods based on the proportion of the photoresist composition, comprising the following steps:
(1) preparation of a nano pigment paste composition: the nano pigment particle and hyperdispersant are added into 0.1 mm zirconium ball grinder with an organic solvent for wet grinding, and the dispersion resin represented by formula (2) is added as a stabilizing resin during the grinding process to prepare a pigment dispersion paste;
(2) preparation of photosensitive liquid: the alkali-soluble resin, light-cured resin with vinyl double bonds, electrically asymmetric active photoinitiator, active aid, resin oligomer of formula (1), and polar organic solvent are mixed and dispersed into solution, and filtered to obtain a photosensitive liquid; and
(3) The pigment dispersion paste in step (1) is mixed with the photosensitive liquid in step (2), and finally a polar organic solvent is added to adjust the viscosity, dispersed in a dispersion machine and filtered to obtain the photoresist composition of the present invention.

In the above steps, the oligomer resin of formula (1) in step (1) and step (2) can adjust the polarity and pH value. The filter used for the filtering mentioned in step (2) has a pore size of 400-1000 nm.

A method for manufacturing graphics on a substrate, comprising the following steps:

The photoresist composition as described above is used to form a photoresist layer on the substrate, and the photoresist layer is soft dried to form a color film; On the color film, the mask plate is used to form graphics on the substrate after exposure, development and low temperature curing. The temperature of low temperature curing is 85-100° C.

Compared with the prior art, the beneficial effects of the present invention at least include:

The dispersion resin of the present invention can stabilize flowing deformation and resist aggregation and flocculation. When used in a photoresist composition, the dispersion resin can enable nano pigments to exist in a dispersed state of fine particles, making the pigment particles unable to agglomerate and flocculate, thereby enabling the photoresist composition to be used to produce fine patterns with high etching accuracy.

### BRIEF DESCRIPTION OF THE DRAWINGS

FIGS. 1A-1D are schematic diagrams of the photolithography process using the photoresist composition of the present invention.

FIG. 2 shows a color photoresist line made on a glass substrate according to the photolithography process illustrated in FIGS. 1A-1D.

FIG. 3 shows a color photoresist line made on an ITO metal substrate according to the photolithography process illustrated in FIGS. 1A-1D.

FIG. 4 shows a color photoresist line made on a PET substrate according to the photolithography process illustrated in FIGS. 1A-1D.

FIGS. 5-7 show colored photoresist graphics made on a PET substrate according to the photolithography process illustrated in FIGS. 1A-1D.

FIG. 8 is a picture of the comparative example 1 not using a filter made of a photoresist composition of resin oligomer in the present invention.

FIG. 9 is the infrared signature spectrum of the disperse resin 2-1 of embodiment 2.

### DETAILED DESCRIPTION OF THE PREFERRED EMBODIMENTS

Formula (4) Examples of intermediate preparation.

Taking the structural formula (X is Br) shown in intermediate 4 and 5 as an example, the intermediate of equation (4) is prepared by the following method.

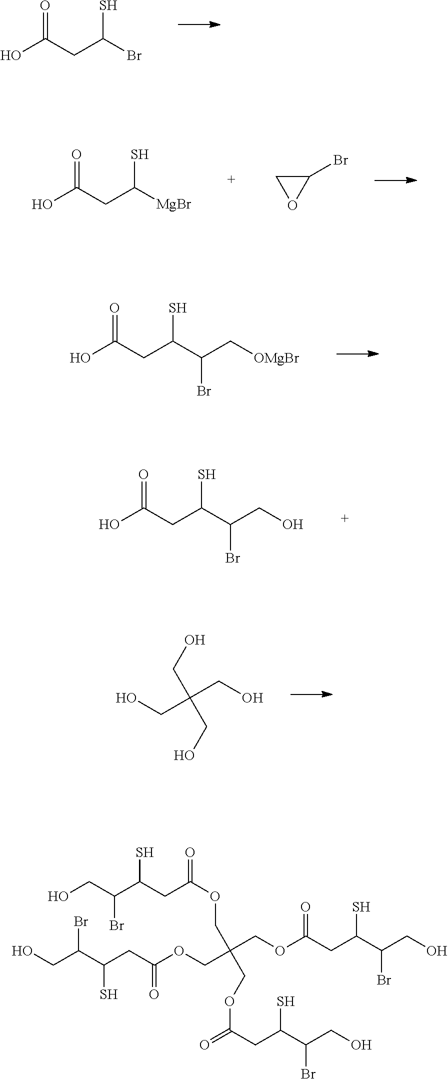

Specifically, starting from a known starting substance, the starting substance is prepared into a Grignard reagent by a known method, and then reacts with 2-bromooxirane (CAS No. 37497-56-6) to obtain an intermediate product, which reacts with pentaerythritol (CAS No. 115-77-5) to produce intermediate 4-5.

Among them, the reaction between the intermediate product and Pentaerythritol is a known method. For details, refer to the preparation method of the compound (CAS No. 31775-89-0) disclosed in Japanese patent JP2011084479A, or refer to the preparation method in known patents CN110647010A and CN111868626A.

The following is a specific embodiment of the present invention, wherein Embodiment 1 is a preparation method of the oligomer resin in the present invention; Embodiment 2 to Embodiment 5 are the preparation methods of the dispersion resin described in the present invention. The reagents involved in the following embodiments are available in the market.

### Embodiment 1

Preparation of Oligomer Resin:

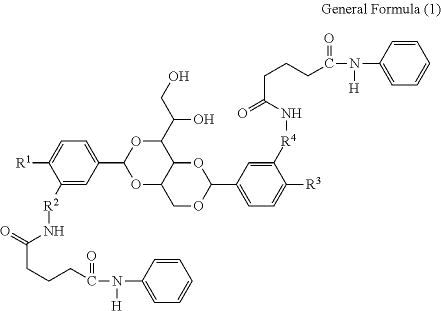

The preparation method for the compound in the above general formula (1) can be obtained by the following synthesis route:

Route:

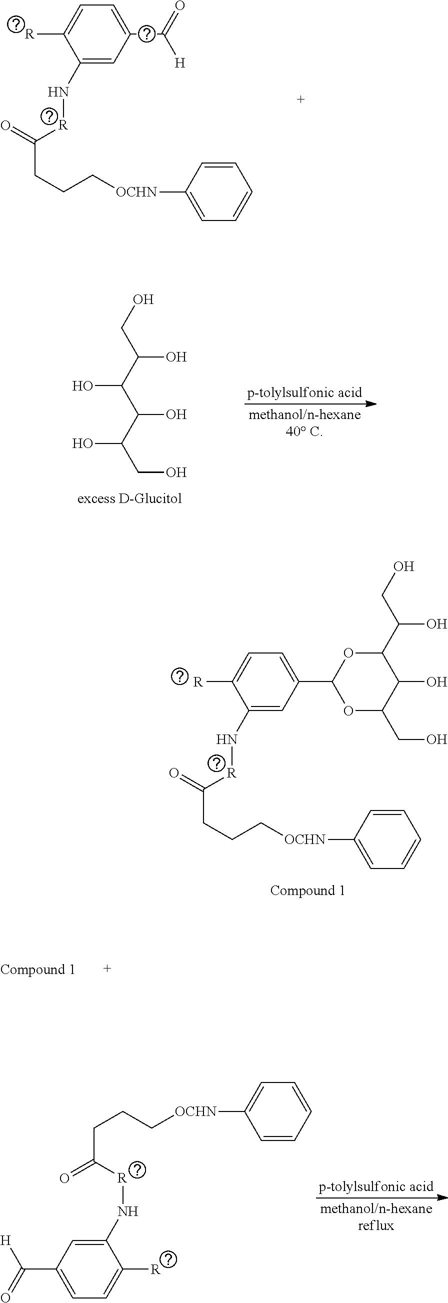

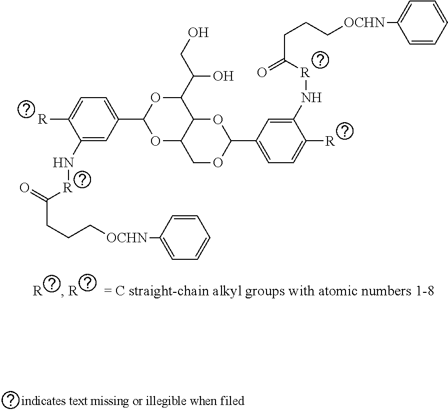

Among them, the initial reactant

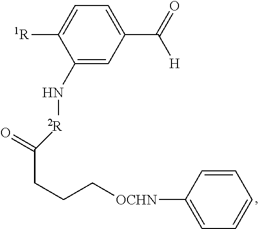

is commissioned by a chemical company to customize the purchase, obtained from the raw material

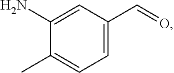

with a molar ratio of 1:3 to D-sorbitol to produce compound 1. Next, the compound 1 and the intermediate containing R4 continue to react in a molar ratio of 1:2 to obtain the general formula (1), for aftertreatment and purification.

In the general formula (1), R1 and R3 can be designed to link a linear hydrocarbon with 2-8 carbon atoms or grafted copolymer groups through a reaction; R2, R4 can be designed as C atom, benzene ring,

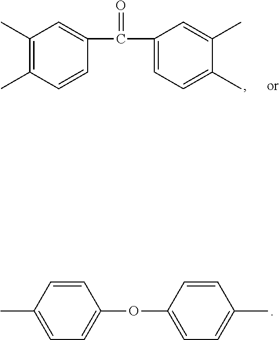

The oligomer (1-1) is obtained.

According to this route, the following can also be obtained:

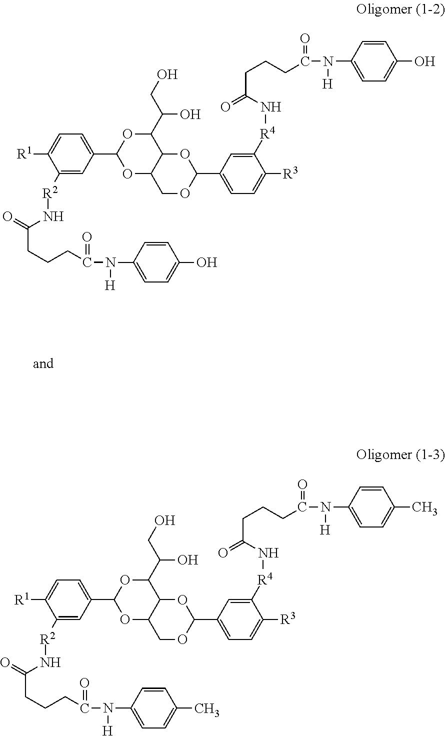

In oligomers (1-1), (1-2) and (1-3), R¹ and R³ each represent linear hydrocarbyl groups or grafted copolymer groups having 2 to 8 carbon atoms; R² and R⁴ each represent C, benzene ring

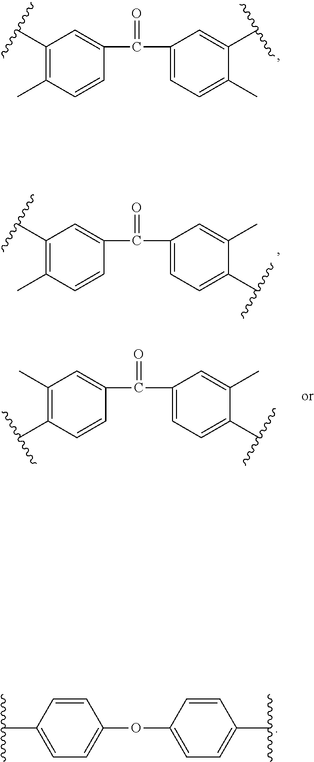

The Mw value of the oligomers (1-1), (1-2) and (1-3) may be 10000-20000; Pd value may be 1.8-2.0.

In this embodiment 1, in the oligomers (1-1), (1-2) and (1-3), R1 is —CH₂CH₂CH₃, R² is

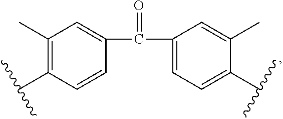

R³ is —CH₃, R⁴ is

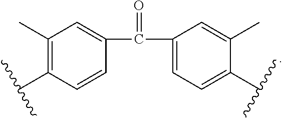

### Embodiment 2

Preparation of Dispersion Resin 2-1:
1) Oligomer synthesis: 15 g of 2-hydroxy-3-phenoxypropyl acrylate, 3.74 g of acrylic acid, 5.41 g of styrene, 5.2 g of methyl methacrylate; 0.58 g of radical initiator 2,2′-azobis(2-methylbutyronitrile); 1.05 g of chain transfer agent α-methylstyrene linear dimer; adding to 50 g of solvent toluene; under nitrogen atmosphere, heating to 90° C., stirring at 300 rpm for 4 Hr, and conducting radical reaction synthesis to obtain oligomer intermediate Z-2; upon characterization, the oligomer intermediate Z-2 has an Mw of 5000-10000, a Pd value of less than 2.5, and viscosity of less than 5000 cps;
2) Product synthesis: putting 36 g of compound 4-5 of general formula (4) (wherein X is Br) and the oligomer intermediate Z-2 obtained in step 1) into four-neck bottle; then adding 60 g of acetonitrile solvent, dissolving 0.08 g of KI catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 95° C., stirring at 350 rpm for 8 Hr, and after the reaction is completed, transferring to a rotary evaporator for rotary evaporation of the solvent; then, adding 180 g of n-butanol again, stir at 55° C. for 1 Hr, and putting it into 540 g of petroleum ether conical flask; after filtering and drying the precipitate, obtaining the dispersion resin 2-1 of the general formula (2). Upon characterization, the dispersion resin 2-1 has an Mw of 16801, and a Pd value of 2.4.

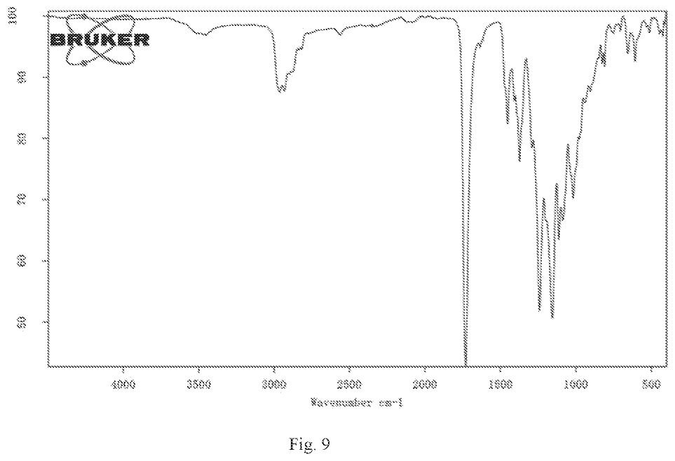

FIG. 9 is the infrared characteristic spectrum of disperse resin 2-1 of the embodiment 2. From the infrared characteristic spectrum, it can be seen that the characteristic absorption peaks of hydroxyl group and sulfhydryl group appear in the infrared characteristic spectrum of disperse resin 2-1, which proves that when compound 4 and 5 (where X is Br) reacts with oligomers, The reaction site of compound 4-5 is Br. According to the infrared characteristic spectrum and the detection results of its properties in the photolithography process, the desired dispersion resin can be obtained by the above-mentioned preparation method.

### Embodiment 3

Preparation of Dispersion Resin 2-2:
1) Oligomer synthesis: 15 g of 2-hydroxy-3-phenoxypropyl acrylate, 4.47 g of methacrylic acid, 5.2 g of methyl methacrylate, 7.4 g of benzyl acrylate; 0.6 g of radical initiator azodiisobutyronitrile; 1.05 g of chain transfer agent α-methyl styrene linear dimer; adding to 60 g of solvent ethyl acetate; under nitrogen atmosphere, heating to 80° C., stirring for 4 Hr at 300 rpm, and conducting radical reaction synthesis to obtain the oligomer intermediate Z-3; upon characterization, the oligomer intermediate Z-3 has an MW of 3000-10000, a Pd value of less than 2.5, and viscosity of less than 5000 cps.
2) Product synthesis: putting 40 g of compound 4-6 of general formula (4) (wherein X is Br) and the oligomer intermediate Z-3 obtained in step 1) into four-neck bottle; then adding 80 g of acetonitrile solvent, dissolving 0.08 g of KI catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 180 g of n-butanol again, stirring at 55° C. for 1 Hr, and putting it into 540 g of petroleum ether conical flask; after filtering and drying the precipitate, obtaining the dispersion resin 2-2 of the general formula (2). Upon characterization, the dispersion resin 2-2 has an Mw of 20350, and a Pd value of 2.3.

### Embodiment 4

Preparation of Dispersion Resin 2-3:
1) Oligomer synthesis: 15 g of 2-hydroxy-3-phenoxypropyl acrylate, 3.74 g of acrylic acid, 5.41 g of styrene, 5.2 g of methyl methacrylate, 7.4 g of benzyl acrylate; adding to 80 g of solvent ethyl acetate; adding 0.8 g of radical initiator azodiisobutyronitrile and 1.05 g of chain transfer agent α-methylstyrene linear dimer into 1.05 g of constant pressure funnel, and then dripping 10 g of ethyl acetate in 30 min; under nitrogen atmosphere, heating to 90° C., stirring for 4 Hr at 300 rpm, and conducting radical reaction synthesis to obtain the oligomer intermediate Z-4; upon characterization, the oligomer intermediate Z-4 has an MW of 3000-10000, a Pd of less than 2.5, and viscosity of less than 5000 cps.
2) Product synthesis: putting 42 g of compound 4-9 of general formula (4) (wherein X is I) and the oligomer intermediate Z-4 obtained in step 1) into four-neck bottle; then adding 80 g of DMF solvent, dissolving 0.08 g of triethylamine catalyst into 20 g of DMF, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 200 g of n-butanol again, stir at 55° C. for 1 Hr, and putting it into 600 g of petroleum ether conical flask; after filtering and drying the precipitate, obtaining the resin 2-3 of the general formula (2). Upon characterization, the dispersion resin 2-3 has an Mw of 17168, and a Pd value of 1.8.

### Embodiment 5

Preparation of Dispersion Resin 2-4:

1) Oligomer synthesis: 15 g of 2-hydroxy-3-phenoxypropyl acrylate, 4.47 g of methacrylic acid, 5.41 g of styrene, 11.55 g of isobornyl methacrylate; 0.8 g of radical initiator azodiisobutyronitrile; 1.05 g of chain transfer agent α-methylstyrene linear dimer; adding to 65 g of solvent ethyl acetate; under nitrogen atmosphere, heating to 90° C., stirring for 4 Hr at 300 rpm, and conducting radical reaction synthesis to obtain the oligomer intermediate Z-5; upon characterization, the oligomer intermediate Z-5 has an MW of 3000-10000, a Pd value of less than 2.5, and viscosity of less than 5000 cps.

2) Product synthesis: putting 40 g of compound 4-11 of general formula (4) (wherein X is I) and the oligomer intermediate Z-5 obtained in step 1) into four-neck bottle; then adding 80 g of DMF solvent, dissolving 0.08 g of KI catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 95° C., stirring at 350 rpm for 8 Hr, and after the reaction is completed, transferring to a rotary evaporator for rotary evaporation of the solvent; then, adding 200 g of n-butanol again, stir at 55° C. for 1 Hr, and putting it into 600 g of petroleum ether conical flask; after filtering and drying the precipitate, obtaining the resin 2-4 of the general formula (2). Upon characterization, the dispersion resin 2-3 has an Mw of 16115, and a Pd value of 2.2.

### Embodiment 6

Preparation of Dispersion Resin 2-5:

1) Oligomer synthesis: 15 g of 2-hydroxy-3-phenoxypropyl acrylate, 3.74 g of acrylic acid, 5.8 g of cyclohexyl methacrylate copolymer, 9.4 g of benzyl methacrylate; 0.6 g of radical initiator azodiisobutyronitrile; 1.05 g of chain transfer agent α-methylstyrene linear dimer; adding to 60 g of solvent ethyl acetate; under nitrogen atmosphere, heating to 80° C., stirring for 4 Hr at 300 rpm, and conducting radical reaction synthesis to obtain oligomer intermediate Z-6; upon characterization, the oligomer intermediate Z-6 has an Mw of 3000-10000, a Pd value of less than 3.5, and viscosity of less than 5000 cps.

2) Product synthesis: putting 40 g of compound 4-8 of general formula (4) (wherein X is Br) and the oligomer intermediate Z-6 obtained in step 1 into four-neck bottle; then adding 80 g of acetonitrile solvent, dissolving 0.08 g of KI catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 180 g of n-butanol again, stir at 55° C. for 1 Hr, and putting it into 540 g of petroleum ether conical flask; after filtering and drying the precipitate, obtaining the dispersion resin 2-5 of the general formula (2). Upon characterization, the dispersion resin 2-5 has an Mw of 21507, and a Pd value of 1.9.

### Embodiment 7

Preparation of Dispersion Resin 2-6:

1) Oligomer synthesis: 158 of 2-hydroxy-3-phenoxypropyl acrylate, 4.47 g of methacrylic acid, 11.2 g of methyl methacrylate, 4.4 g of epoxypropyl methacrylate; 0.6 g of radical initiator azodiisobutyronitrile; 1.05 g of chain transfer agent α-methylstyrene linear dimer; adding to 60 g of solvent ethyl acetate; under nitrogen atmosphere, heating to 90° C., stirring for 4 Hr at 300 rpm, and conducting radical reaction synthesis to obtain the oligomer intermediate Z-7; upon characterization, the oligomer intermediate Z-7 has an MW of 3000-10000, a Pd value of less than 2.5, and viscosity of less than 5000 cps.

2) Product synthesis: putting 40 g of compound 4-11 of general formula (4) (wherein X is I) and the oligomer intermediate Z-7 obtained in step 1 into four-neck bottle; then adding 80 g of acetonitrile solvent, dissolving 0.08 g of triethylamine catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 180 g of n-butanol again, stirring at 55° C. for 1 Hr, and putting it into 540 g of petroleum ether conical flask; after filtering and drying the precipitate, obtaining the dispersion resin 2-6 of the general formula (2). Upon characterization, the dispersion resin 2-6 has an Mw of 22340, and a Pd value of 2.3.

### Embodiment 8

Preparation of Dispersion Resin 2-7:

1) Oligomer synthesis: 15 g of 2-hydroxy-3-phenoxypropyl acrylate, 3.74 g of acrylic acid, 7.6 g of styrene, 6.4 g of 2-hydroxyethyl methacrylate; 0.6 g of radical initiator azodiisobutyronitrile; 1.05 g of chain transfer agent α-methyl styrene linear dimer; adding to 60 g of solvent ethyl acetate; under nitrogen atmosphere, heating to 80° C., stirring for 4 Hr at 300 rpm, and conducting radical reaction synthesis to obtain the oligomer intermediate Z-8; upon characterization, the oligomer intermediate Z-8 has an MW of 3000-10000, a Pd value of less than 2.5, and viscosity of less than 5000 cps.

2) Product synthesis: putting 40 g of compound 4-3 of general formula (4) (wherein X is Br) and the oligomer intermediate Z-8 obtained in step 1 into four-neck bottle; then adding 80 g of acetonitrile solvent, dissolving 0.08 g of K1 catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 180 g of n-butanol again, stirring at 55° C. for 1 Hr, and putting it into 540 g of petroleum ether conical flask; after filtering and drying the precipitate, obtaining the dispersion resin 2-7 of the general formula (2); Upon characterization, the dispersion resin 2-7 has an Mw of 16579, and a Pd value of 2.1.

### Embodiment 9

Preparation of Dispersion Resin 2-8:

1) Oligomer synthesis: 15 g of 2-hydroxy-3-phenoxypropyl acrylate, 4.47 g of methacrylic acid, 4.7 g of methyl methacrylate, 8.8 g of benzyl methacrylate; 0.6 g of radical initiator azodiisobutyronitrile; 1.05 g of chain transfer agent α-methylstyrene linear dimer; adding to 60 g of solvent ethyl acetate; under nitrogen atmosphere, heating to 80° C., stirring for 4 Hr at 300 rpm, and conducting radical reaction synthesis to obtain the oligomer intermediate Z-9; upon characterization, the oligomer intermediate Z-9 has an MW of 3000-10000, a Pd value of less than 2.5, and viscosity of less than 5000 cps.

2) Product synthesis: putting 40 g of compound 4-5 of general formula (4) (wherein X is I) and the oligomer intermediate Z-9 obtained in step 1 into four-neck bottle; then adding 80 g of acetonitrile solvent, dissolving 0.08 g of triethylamine catalyst into 20 g of acetonitrile, putting in a constant pressure funnel, connecting it to a four-neck bottle, and dripping it in 30 minutes; at the same time, after magnetic stirring, heating, dissolving and refluxing for 4-5 Hr, maintaining the reaction heating temperature of 90° C., stirring at 350 rpm for 8 Hr, and after the reaction is completed, transferring to a rotary evaporator for rotary evaporation of the solvent; then, adding 180 g of n-butanol again, stirring at 55° C. for 1 Hr, and putting it into 540 g of petroleum ether conical flask; after filtering and drying the precipitate, obtaining the dispersion resin 2-8 of the general formula (2). Upon characterization, the dispersion resin 2-8 has an Mw of 22790, and a Pd value of 2.5.

Embodiments 10 to 15 and comparative examples 1-2 are photoresist compositions prepared using the resin oligomer and dispersion resin obtained from Embodiments 1-9 above. The consumption of components and raw materials in Embodiments 10 to 15 and comparative examples 1 and 2 is as shown in Table 2. The preparation method of the photoresist composition is as follows:
(1) preparation of nano pigments paste composition: the nano pigments particle and hyperdispersant are added into 0.1 mm zirconium ball grinder with an organic solvent for wet grinding, and the resin oligomer with the structural unit represented by formula (1) is added as a stabilizing resin during the grinding process to prepare a pigment dispersion paste;
(2) Preparation of photosensitive liquid: the alkali-soluble resin, light-cured resin with vinyl double bonds, electrically asymmetric photoinitiator, active aid, resin oligomer of formula (1), and polar organic solvent are mixed and dispersed into solution, and filtered by a filter with pore size of 400-1000 nm to obtain a photosensitive liquid;
(3) the pigment dispersion paste in step (1) is mixed with the photosensitive liquid in step (2), and finally a polar organic solvent is added to adjust the viscosity, dispersed in a dispersion machine and filtered to obtain the photoresist composition.

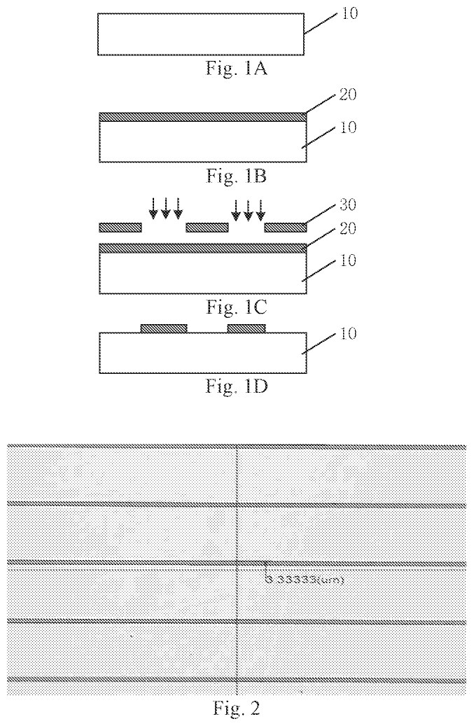

Referring to FIGS. 1A to 1D, the photoresist compositions of Embodiments 6 to 11 and comparative examples land 2 are developed into graphics according to the following methods:
(1) treatment of a substrate 10: vacuum attachment and fixation on a substrate; or load rolls by means of a Roll-to-Roll device the substrate 10 may be glass/PET/PI/metal substrate;
(2) making a photoresist layer: rotating/Slit coating/printing or spraying the photoresist composition as described in the present invention on the substrate 10, and then successively undergoing vacuum and prebaking (70-100° C./2-5 min) to form the first layer 2-5 μm color film 20;
(3) making pixel graphics: using a mask 30 on the color film 20 in step (2) above to mask, UV exposure, development, and low temperature curing to form graphics on the mask.

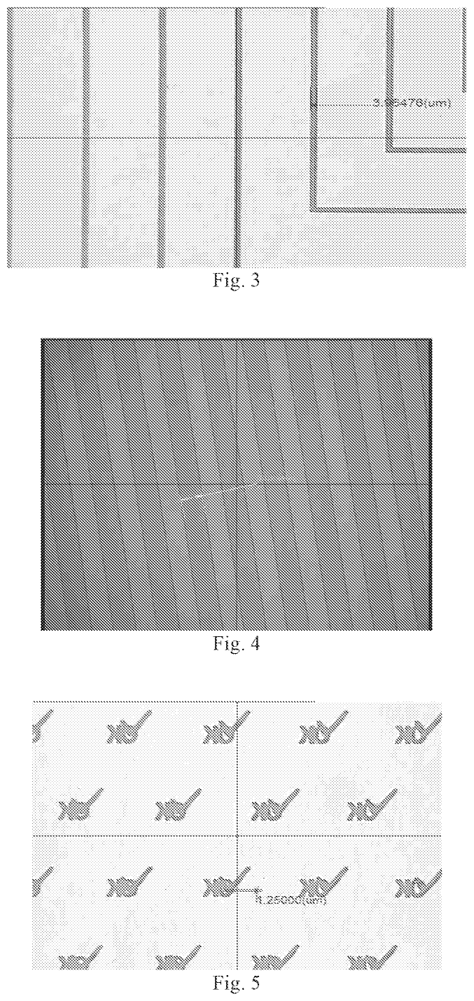

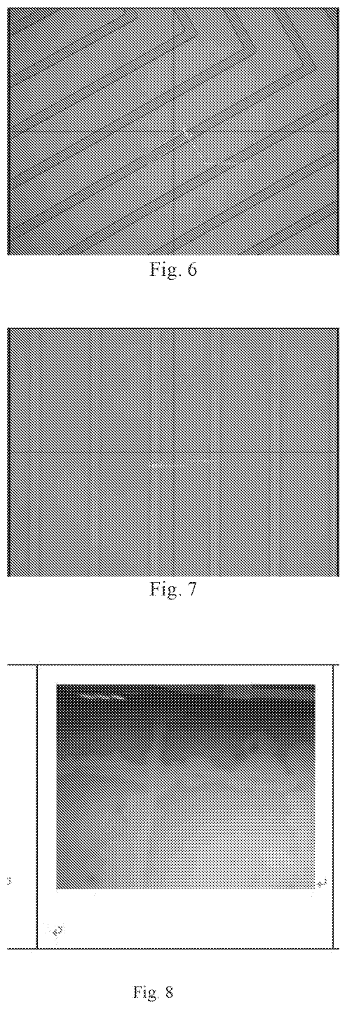

Referring to FIGS. 2 to 7, FIG. 2 (Embodiment 10) shows that, according to the photolithography technique illustrated in FIGS. 1A-1D, the color photoresist lines made on a glass substrate are magnified 5000 times under a metallographic microscope and CCD, and the measured width is 3.3 μm. FIG. 3 (Embodiment 11) shows that, according to the photolithography technique illustrated in FIGS. 1A-1D, the color photoresist lines made on an ITO metal substrate are magnified 5000 times under a metallographic microscope and CCD, and the measured width is 3.9 μm. FIG. 4 (Embodiment 12) shows that, according to the photolithography technique illustrated in FIGS. 1A-1D, the color photoresist lines made on a PET substrate are magnified 5000 times under a metallographic microscope and CCD, and the measured width is 20.0 μm. FIGS. 5-7 (corresponding to Embodiments 13-15) show that, according to the photolithography technique illustrated in FIGS. 1A-1D, the color photoresist graphics made on an ITO metal substrate are magnified 5000 times under a metallographic microscope and CCD, and the measured minimum spacing is 1.2-3.3 μm. From FIG. 2 to FIG. 7, the photoresist composition of the present invention can be used for making fine graphics with high photolithography accuracy.

In order to reflect the effect of the photoresist composition of the present invention, nano pigments PR254 and C Black 7 are also directly used as two groups of comparative embodiments.

TABLE 1
Photolithography Development lines in Embodiments 10to 15 and Comparative Examples 1 and 2

| | | | | | | | Comparative | Comparative |
|---|---|---|---|---|---|---|---|---|
| Raw | Embodi- | Embodi- | Embodi- | Embodi- | Embodi- | Embodi- | example | example |
| materials | ment 10 | ment 11 | ment 12 | ment 13 | ment 14 | ment 15 | 1 | 2 |
| Nano | PR254 | PY150 | PB15:6 | PG58 | TiO2 | C black 7 | PR254 | C black 7 |
| pigment | 3 parts | 3 parts | 3 parts | 3 parts | 3 parts | 3 parts | 3 parts | 3 parts |
| Hyperdispersant | Byk-2001 | Byk-163 | Byk-161 | Byk-2001 | EFKA-4047 | EFKA-4047 | Byk-2001 | EFKA-4047 |
| | 0.2 parts | 0.2 parts | 0.2 parts | 0.2 parts | 0.2 parts | 0.2 parts | 0.2 parts | 0.2 parts |
| Dispersion | 2-1 | 2-2 | 2-3 | 2-2 | 2-4 | 2-5 | — | 2-2 |
| resin | 0.5 parts | 0.5 parts | 0.5 parts | 0.5 parts | 0.5 parts | 0.5 parts | | 0.5 parts |
| Organic | EEP | EEP | EEP | EEP | EEP | EEP | EEP | EEP |
| solvent | 6 parts | 6 parts | 6 parts | 6 parts | 6 parts | 6 parts | 6 parts | 6 parts |
| MMA | MMA-ST | MMA-ST | MMA-ST | MMA-ST | MMA-ST | MMA-ST | MMA-ST | MMA-ST |
| alkyl | copolymer | copolymer | copolymer | copolymer | copolymer | copolymer | copolymer | copolymer |
| resin | 2.2 parts | 2 parts | 1 part | 1 part | 1 part | 1 part | 2.5 parts | 2.5 parts |
| Light-cu | DPPA | DPPA | DPPA | DPPA | DPPA | DPPA | DPPA | DPPA |
| red resin | 2.5 parts | 2.5 parts | 2.5 parts | 2.5 parts | 2.5 parts | 2.5 parts | 2.5 parts | 2.5 parts |
| Photoinitiator | 369/907 | 369/907 | 369/907 | 369/907 | 369/907 | 369/907 | 369/907 | 369/907 |
| | 0.1/0.1 | 0.1/0.1 | 0.1/0.1 | 0.1/0.1 | 0.1/0.1 | 0.1/0.1 | 0.1/0.1 | 0.1/0.1 |
| | parts | parts | parts | parts | parts | parts | parts | parts |
| Active | EFKA3883/ | EFKA3883/ | EFKA3883/ | EFKA3883/ | EFKA3883/ | EFKA3883/ | EFKA3883/ | EFKA3883/ |
| aid | KH570 | KH570 | KH570 | KH570 | KH570 | KH570 | KH570 | KH570 |
| | 0.01/0.01 | 0.01/0.01 | 0.01/0.01 | 0.01/0.01 | 0.01/0.01 | 0.01/0.01 | 0.01/0.01 | 0.01/0.01 |
| | parts | parts | parts | parts | parts | parts | parts | parts |
| Resin | Copolymer | Copolymer | Copolymer | Copolymer | Copolymer | Copolymer | — | — |
| oligomer | 1-1 | 1-2 | 1-3 | 1-2 | 1-3 | 1-2 | | |
| | 0.3 parts | 0.5 parts | 1.5 parts | 1.5 parts | 1.5 parts | 1.5 parts | | |
| Polar | PMA | PMA | PMA | PMA | PMA | PMA | PMA | PMA |
| solvent | 15 parts | 15 parts | 15 parts | 15 parts | 15 parts | 15 parts | 15 parts | 15 parts |
| Accuracy | 3 μm | 4 μm | 1.8 μm | 3 μm | 2 μm | 3 μm | 15 μm | 3 μm |
| of | | | | | | | | |
| photolithography | | | | | | | | |
| development | | | | | | | | |
| lines | | | | | | | | |
| Pixel | OK | OK | OK | OK | OK | OK | OK | NG |
| shedding | | | | | | | | |

The photoresist composition of Embodiments 10 to 15 above is used for low temperature curing (90° C.) to produce monochromatic filters, which can be achieved through the following process:
1) Coating: 1-2 μm thick coating, with vacuum of −1 atm/30 s;
2) Prebaker: baking the coated substrate for 160 s at 85° C.;
3) Exposure: The exposure energy is 100-200 mj/cm², and the Gap value of the mask is
4) Developing: using 0.238% TMAH alkaline developing solution to develop for 60-100 S into the corresponding graphics on the mask; and
5) Postbaker: baking at 90° C. for 60 min.

After using the dispersion resin of the present invention in Embodiments 10 to 15 and Comparative Example 2, the accuracy of the photolithography development line can reach below 4 μm; The accuracy of the photolithography development line without using the dispersion resin of the present invention in Comparative Example 1 can only reach 15 μm. This indicates that the dispersion resin of the present invention matches the polarity of other components such as the developing resin in the photoresist, resulting in improved pixel accuracy, especially the resolution of pixel edges, after UV lithography and low temperature postbaking. In addition, the resin oligomer of the present invention is not used in both Comparative Example 1 and Comparative Example 2, resulting in reduced pixel adhesion after the low temperature postbaking process and shedding of pixels below 4 μm; However, the pixel adhesion of the photoresist formulation using the resin oligomer of the present invention after the baking process at a low temperature of 90° C. does not exhibit any shedding, as shown in FIG. 8.

The performances of the filter is detected, with the results as shown in Table 2.

TABLE 2
Detection Results of Monochromatic Filters in Embodiments
10to 15 and Comparative Examples 1 and 2

| | 10 μm | 10 μm | | | | 10 μm | 10 μm |
|---|---|---|---|---|---|---|---|
| | line | line acid | | | | line dual | line dual |
| Contrast | solvent | & alkali | CD | Film | | 8524H | 85240H |
| sample | resistance | resistance | Loss/μm | thickness | Slope | adhesion | adhesion |
| Embodiment | Δ | Δ | 0.3 | 1.5 | 5.36 | ◯ | Δ |
| 10 | | | | | | | |
| Embodiment | Δ | Δ | 0.3 | 1.4 | 5.28 | ◯ | Δ |
| 11 | | | | | | | |
| Embodiment | Δ | ◯ | 0.2 | 1.3 | 3.97 | ◯ | ◯ |
| 12 | | | | | | | |
| Embodiment | ◯ | ◯ | 0.3 | 1.6 | 4.83 | ◯ | ◯ |
| 13 | | | | | | | |
| Embodiment | Δ | Δ | 0.3 | 1.5 | 5.51 | ◯ | ◯ |
| 14 | | | | | | | |
| Embodiment | Δ | Δ | 0.2 | 1.5 | 4.99 | ◯ | ◯ |
| 15 | | | | | | | |
| Comparative | ● | ● | 1.2 | 1.4 | 5.32 | ● | ● |
| example 1 | | | | | | | |
| Comparative | ● | ● | 0.2 | 1.5 | 5.62 | ● | ● |
| example 2 | | | | | | | |

Note:
● indicates shedding of pixel lines;
Δ indicates no shedding of pixel lines, but the para-position patch marker has shedding;
◯ indicates that pixels and markers do not have shedding;
Slope value, film thickness and CD Loss are in μm.

As shown in Table 2, after the monochromatic filter used in Embodiments 12 to 15 is subjected to postbaking of 90° C. photolithography process, solvent resistance, acid and alkali resistance, CD loss, and 10 μm line dual 85 adhesion and other properties are good.

After a small amount of resin oligomer of the present invention is added in Embodiments 10 and 11, and the monochromatic color filter made therefrom is subjected to postbaking of 90° C. photolithography process, the solvent resistance, acid and alkali resistance, CD loss, and 10 μm line dual 85 adhesion and other properties are improved.

The oligomer resin of the present invention is not used in Comparative Examples 1 and 2, and after the monochromatic color filter made therefrom is subjected to postbaking of 90° C. photolithography process, the solvent resistance, acid and alkali resistance, CD loss, and 10 μm line dual 85 adhesion and other properties are NG.

The above embodiments are only preferred embodiments of the present invention and cannot be used to define the scope of protection of the present invention. Any insubstantial changes and replacements made by those skilled in the art based on the present invention fall within the scope of protection required by the present invention.

What is claimed is:

1. A dispersion resin is characterized in that the dispersion resin is expressed by formula (2):
(Z-A)ₙ—Rₘ (2),
in formula (2), n=1-5, m=1-5, and n+m≤6;
Z represents H, or an acrylic copolymer containing an amino group, an epoxy group, an alkyl group having 1-14 carbon atoms, a cycloalkyl group having 3-14 carbon atoms or an aryl substituent;
R represents C, N, CH groups, 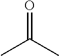
or at least one of linear alkyl containing 2-14 carbon atoms, aliphatic cycloalkyl containing 2-14 carbon atoms, aryl group and heteroaryl group containing 3-14 carbon atoms;
A is represented by formula (3): 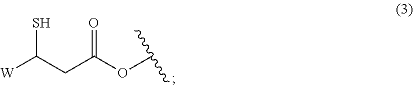
and
in formula (3), W is connected to Z, the carboxyl group is linked to R, and W represents at least one of an H atom, a substituted or unsubstituted alkyl group having 1-14 carbon atoms, an alkylene oxide group having 2-6 carbon atoms, a substituted or unsubstituted aryl group and a substituted or unsubstituted heteroaryl group having 3-14 carbon atoms.

2. The dispersion resins described in claim 1 are characterized by,
n=1-3, m=1-3, and n+m≤4, and/or
Z represents a copolymer formed by more than one compound selected from the group consisting of methacrylic acid, acrylic acid, benzyl acrylate, styrene, methyl methacrylate, butyl methacrylate, isobornyl methacrylate, glycidyl methacrylate, dicyclopentanyl methacrylate, hydroxyethyl methylacrylate, hydroxybutyl acrylate, N-phenyl maleimide, maleic anhydride, 2-acrylic acid-2 hydroxy-3-phenoxypropyl acrylate or pentaerythritol acrylate, and/or
W represents at least one of H, methyl, ethyl, and hydroxy substituted alkyl, epoxy alkyl, phenyl, benzyl, and phenolic groups; and
Z represents an acrylic copolymer with an Mw of 5000-10000, a Pd value of less than 2.5, and a viscosity of less than 5000 cps.

3. The dispersion resins referred to in claim 1 are characterized by the fact that A represents at least one of the compounds represented by the following:

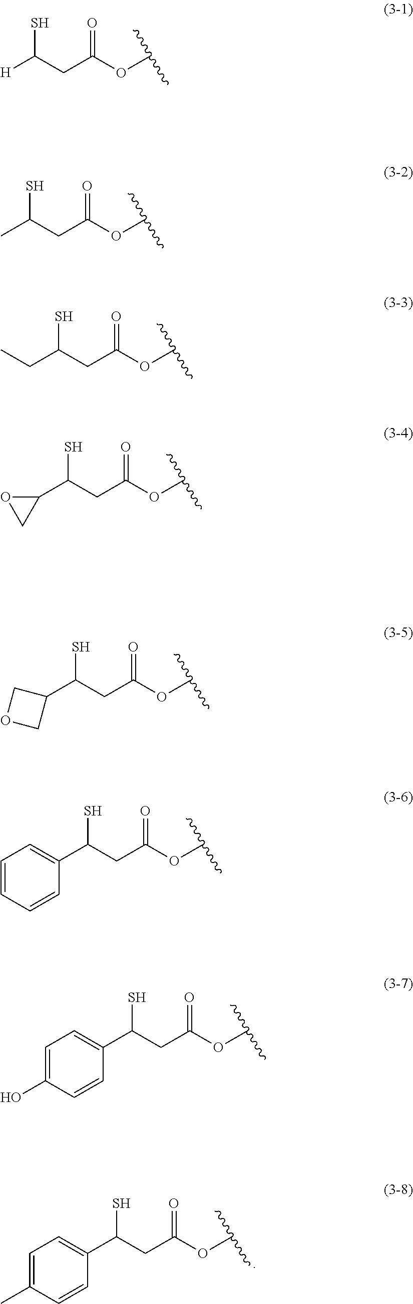

4. An intermediate used for preparing the dispersion resin according to claim 1 is represented by formula (4):
(X-A)ₙ—Rₘ (4),
in formula (4), X represents halogen;
n=1-5, m=1-5, and n+m≤6;
R represents C, N, CH groups, 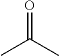
or at least one of linear alkyl containing 2-14 carbon atoms, aliphatic cycloalkyl containing 2-14 carbon atoms, aryl group and heteroaryl group containing 3-14 carbon atoms;
A is represented by formula (3): 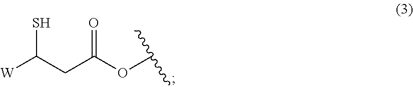
and
in Formula (3), W is connected to X, and carboxyl group is connected to R, where W represents H atom, saturated or unsaturated alkyl group with 1 to 14 carbon atoms, epoxy group with 2 to 6 carbon atoms, substituted or unsubstituted aryl group with 3 to 14 carbon atoms, and at least one of substituted or unsubstituted heteraryl group.

5. According to claim 4, the dispersion resin is characterized by,
X is Cl, Br or I,
n=1-3, m=1-3, and n+m≤4, and/or
W represents at least one of H, methyl, ethyl, hydroxy substituted alkyl, epoxy alkyl, phenyl, benzyl, and phenolic groups.

6. The intermediate according to claim 4 is one of the compounds represented by the following:

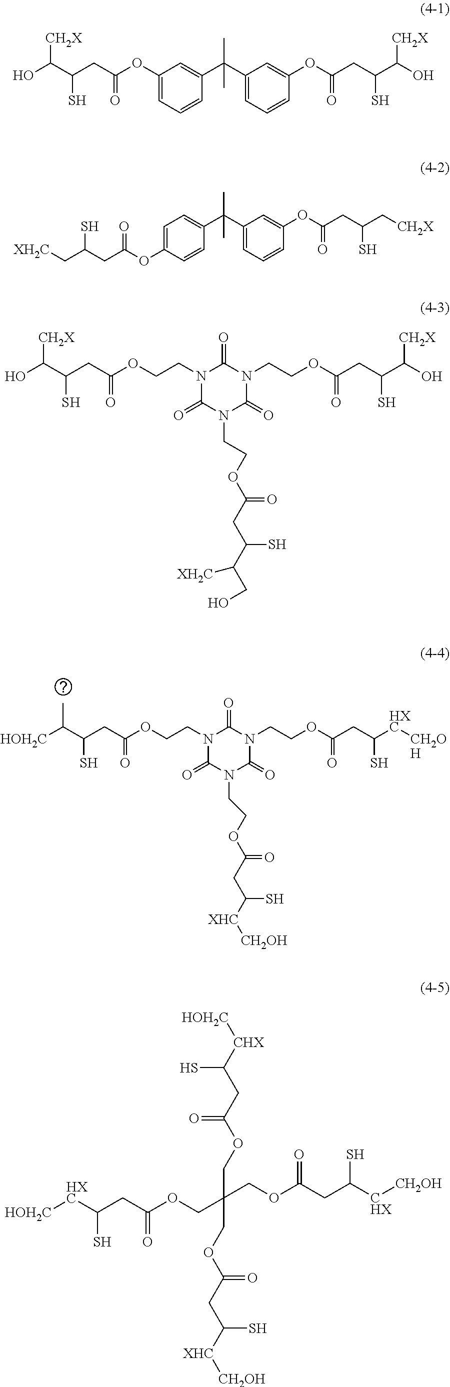

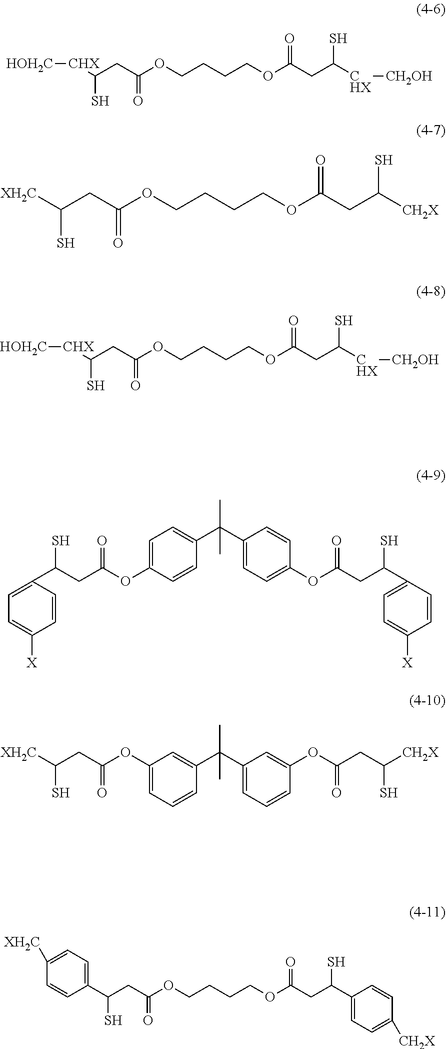

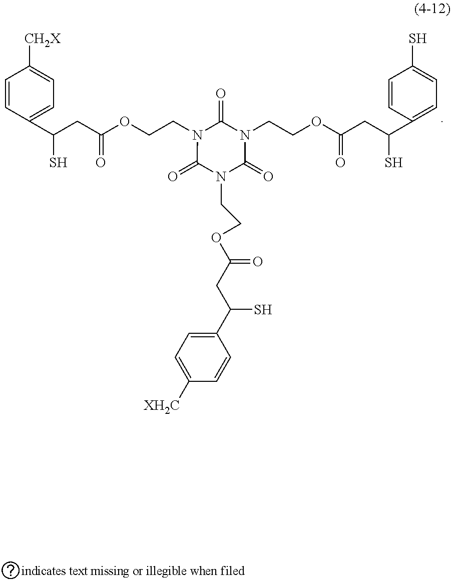

7. A method for preparing the dispersion resin according to claim 1, comprises the following steps:
under the action of a radical initiator, acrylic compounds containing amino groups, epoxy groups, alkyl groups having 1-14 carbon atoms, and cycloalkyl group or aryl substituents having 3-14 carbon atoms are added to a first solvent containing a chain transfer agent, and an acrylic copolymer Z is generated through radical solution polymerization under an inert atmosphere; and the obtained acrylic copolymer Z is reacted with the intermediate according to any one of claims 4 to 6 in the presence of a catalyst in a second solvent to generate the dispersion resin.

8. According to the method described in claim 7, it is characterized by, the obtained acrylic copolymer Z and the intermediates are heated in the presence of a catalyst, dissolved in a second solvent for 2-5 Hr, and stirred for 5-12 hr at 70˜120° C. to react to generate the dispersion resin, and/or
the mass ratio of the acrylic copolymer Z to the intermediate is 1:1 to 1.5:1.

9. According to the method described in claim 8, it is characterized by, the obtained acrylic copolymer Z is reacted with the intermediate in the presence of a catalyst, after heated dissolution reflux of 3.5 Hr in a second solvent, and stirred 8 Hr at 90° C. to generate the dispersion resin, and/or
the mass ratio of the acrylic copolymer Z to the intermediate is 1.2:1.

10. The method described in claim 7 is characterized by, the acrylic compound is more than one compound selected from the group consisting of methacrylic acid, acrylic acid, benzyl acrylate, styrene, methyl methacrylate, butyl methacrylate, isobornyl methacrylate, glycidyl methacrylate, dicyclopentanyl methacrylate, hydroxyethyl methylacrylate, hydroxybutyl acrylate, N-phenyl maleimide, maleic anhydride, 2-acrylic acid-2 hydroxy-3-phenoxypropyl acrylate or pentaerythritol acrylate, and/or
the first solvent and the second solvent are each at least one selected from the group consisting of toluene, ethyl acetate, DMF, NMP, DMSO, and acetonitrile, and/or
the catalyst is at least one selected from the group consisting of tetramethyl guanidine, TMG, KI, NaI, triethylamine, and metformin.

11. A nano pigment paste composition comprises the following components by weight parts:
5-30 parts of nano pigment;
0.5-5 parts of hyperdispersant;
0.5-5 parts of the dispersion resin according to claim 1; and
15-75 parts of organic solvent.

12. The nano pigment paste composition according to claim 11 has an average particle size D₅₀ of 20-200 nm, a bulk density of 0.7-1.8 g/cm³, and a specific surface area of 100-200 m²/g.

13. The nano pigment paste composition according to claim 11, characterized in that,
the nano pigment is at least one of red, yellow, blue, green, black, and white organic and/or inorganic nano pigments, and/or
the hyperdispersant is at least one of a copolymer of methacrylic acid and styrene, a polyester copolymer, a polyurethane copolymer, and an epoxy resin copolymer, and/or
the organic solvent is at least one of propylene glycol monomethyl ether, propylene glycol methyl ether acetate, ethyl 3-ethoxypropionate, and butyl acetate.

14. A photoresist composition, comprises the following components by weight parts:
claim 11 of the nano-pigment pigment paste compositions 1-50 copies;

| | | |
|---|---|---|
| alkali-soluble resin | 1-20 | parts; |
| resin oligomer | 1-20 | parts; |
| photoinitiator | 0.2-2 | parts; |
| active aid | 0.02-2 | parts; |
| light-cured resin | 1-15 | parts; and |
| polar organic solvent | 20-200 | parts. |

15. The photoresist composition according to claim 14, characterized in that,
the alkali-soluble resin is at least one selected from the group consisting of a methacrylic acid—methyl methacrylate copolymer, a methacrylic acid—cyclohexyl methacrylate copolymer,
a methacrylic acid—epoxypropyl methacrylate copolymer, a methacrylic acid-2-hydroxyethyl methacrylate copolymer, a methacrylic acid—cyclohexyl methacrylate copolymer, and a styrene-2-hydroxyethyl methacrylate copolymer, and/or
the light-cured resin is at least one selected from the group consisting of acrylated epoxidized soybean oil, modified epoxy acrylate, polyester acrylate, active amine, HDDA, TMPTA, DPGDA, PETA, IOBA, EB114, EB145, EB160, ODA, TCDA and OTA480; 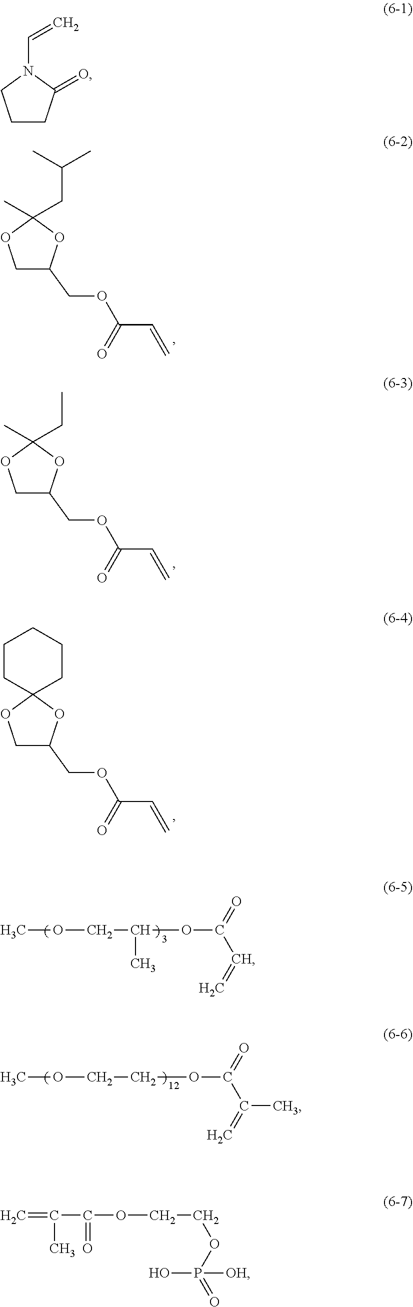 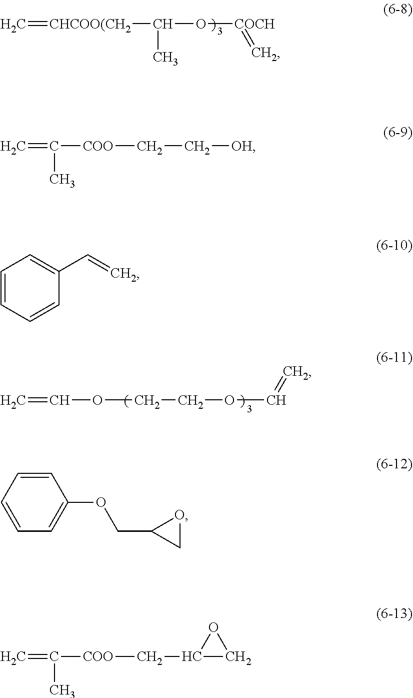
the photoinitiator is at least one selected from the group consisting of diphenyl (2,4,6-trimethylbenzoyl) phosphine oxide, 1-hydroxycyclohexylphenyl ketone, 2-benzyl-2-(dimethylamino)-4′-morpholinobutyryl benzene, 2-methyl-1-[4-methylthiophenyl]-2-morpholinopropan-2-one, 2-hydroxy-2-methyl-1-phenyl-1-acetone, 2-isopropylthioxanthone, 4-dimethylaminobenzoate, 4-dimethylaminobenzoate 2-ethylhexyl acrylate, methyl o-benzoylbenzoate, 4-methylbenzophenone; 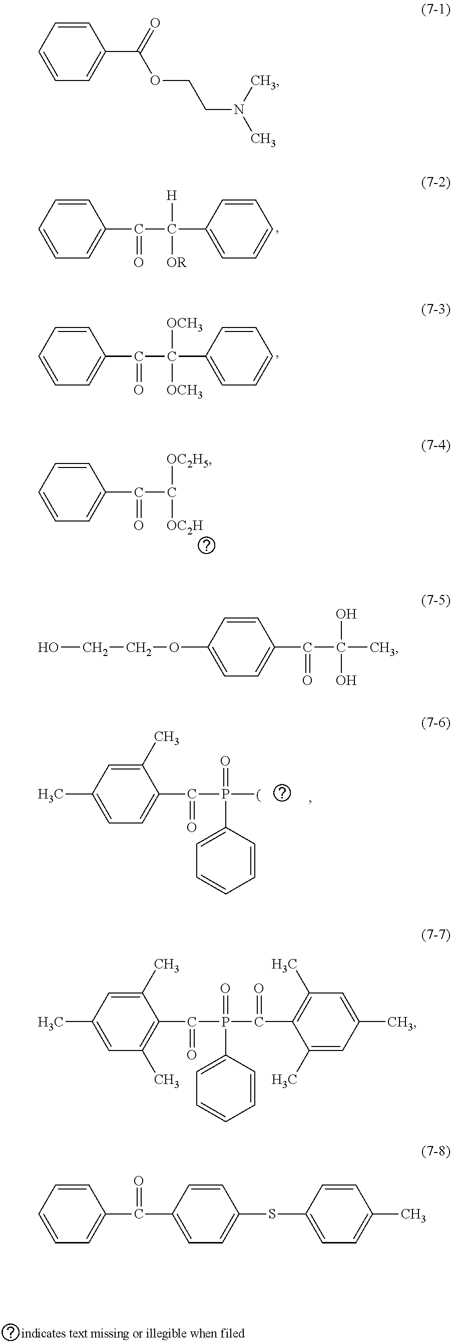
the active aid is at least one of a flatting agent and a coupling agent, wherein the flatting agent is at least one selected from the group consisting of a polyether modified polydimethylsiloxane solution, a polyester modified polydimethylsiloxane solution, a polyether modified polysiloxane solution, a polyester modified polymethylalkylsiloxane solution, a polyether modified polydimethylsiloxane solution, a polyether modified polydimethylsiloxane solution, a polyacrylate solution and a fluorocarbon copolymer solution, and the coupling agent is at least one selected from the group consisting of N′-β′-aminoethyl-N-β-aminoethyl-γ-aminopropylmethyldimethoxysilane, N′-β′-aminoethyl-N-β-aminoethyl-γ-aminopropylmethyldimethoxysilane, N-β′-aminoethyl-N-β-aminoethyl-γ-aminopropylmethyldiethoxysilane, N′-β′-aminoethyl-N-β-aminoethyl-γ-aminopropyltrimethoxysilane, N′-β′-aminoethyl-N-β-aminoethyl-γ-aminopropyltriethoxysilane and N′-β′-aminoethyl-N-β-aminoethyl-α-aminomethyl triethoxysilane, γ-cyclohexylaminopropyltriethoxysilane and methyl, γ-cyclohexylaminopropyldimethoxysilane and γ-chloropropyltriethoxysilane, and/or
the polar organic solvent is at least one selected from the group consisting of methyl ethyl ketone, ethyl cellosolve, glycol dimethyl ether, ethylene glycol diethyl ether, propylene glycol dimethyl ether, diethylene glycol dimethyl ether, 2-ethoxypropanol, 2-methoxypropanol, 3-methoxybutanol, cyclohexanone, cyclopentanone, propylene glycol methyl ether acetate, propylene glycol diethyl ether acetate, and butyl acetate, and/or
the resin oligomer is represented by formulae (1-1), (1-2) or (1-3): 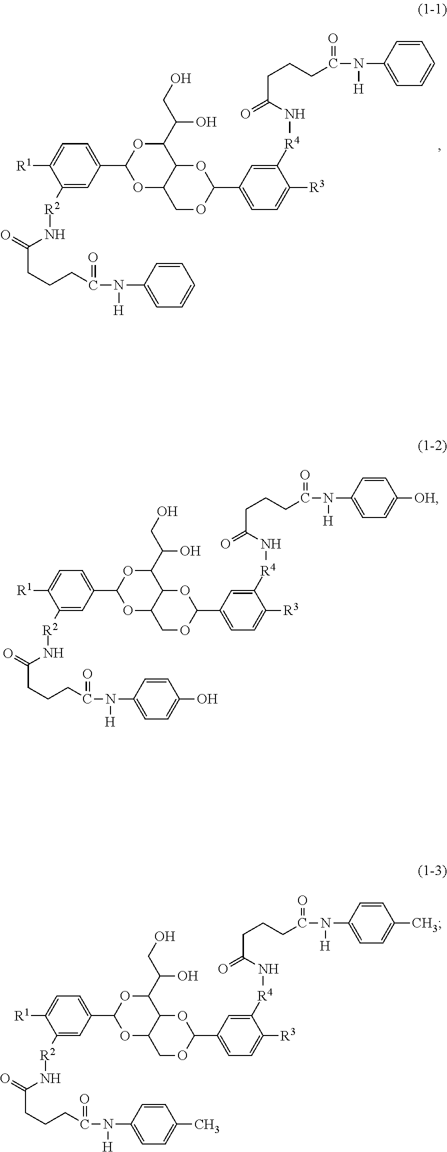
and
in formulae (1-1), (1-2) and (1-3), R¹ and R³ each represent linear hydrocarbyl group or grafted copolymer groups having 2-8 carbon atoms, and R² and R⁴ each represent C, benzene ring

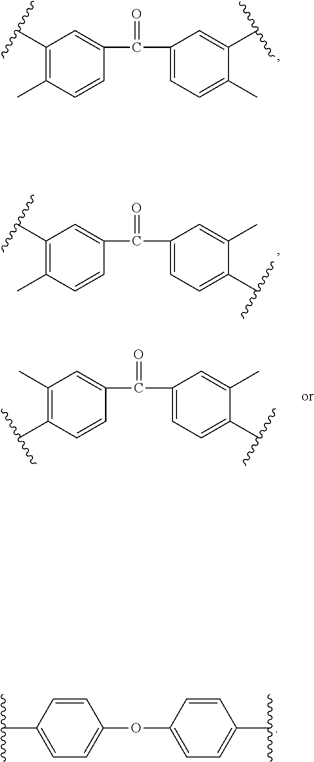

16. A method for manufacturing graphics on a substrate, characterized by comprising the following steps:
a photoresist layer is formed on the substrate by using the photoresist composition according to claim 14, and the photoresist layer is dried to form a color film; and
on a color film, graphics are formed on a substrate using a mask after exposure,
development, and low temperature curing, the low temperature curing temperature being 85-100° C.

17. A use of the dispersion resin according to claim 1 in the preparation of the nano pigment paste composition or photoresist.
